(19) United States
(12) Patent Application Publication
(10) Pub. No.: US 2010/0013537 A1
(43) Pub. Date: Jan. 21, 2010

(54) LOW-VOLTAGE DIFFERENTIAL SIGNALING RECEIVER WITH COMMON MODE NOISE SUPPRESSION

(75) Inventors: Selim Eminoglu, Camarillo, CA (US); Anders K. Petersen, Carpinteria, CA (US)

Correspondence Address: Snell & Wilmer L.L.P. (TELEDYNE), 600 ANTON BOULEVARD, SUITE 1400, COSTA MESA, CA, 92626, US

(73) Assignee: TELEDYNE SCIENTIFIC & IMAGING, LLC, THOUSAND OAKS, CA (US)

(21) Appl. No.: 12/173,793

(22) Filed: Jul. 15, 2008

(51) Int. Cl. H03L 5/00

(52) U.S. Cl. 327/306

(57) ABSTRACT

The disclosure relates to a method and apparatus for noise suppression in an LVDS receiver by providing improved common mode noise immunity through a bypass circuit. In one embodiment, the disclosure relates to an apparatus for providing Low Voltage Differential signaling (LVDS). The apparatus includes a preamplifier circuit for receiving a DC component of a first signal and providing a first processed DC signal; a first bypass circuit for receiving an AC component of the first signal, the first bypass circuit providing a first AC output signal; a first node for combining the processed DC signal with the first AC output signal to form a first combined output signal; and an amplifier circuit for amplifying the first combined output signal and a second signal to provide a first amplified signal and a second amplified signal, wherein the first bypass circuit is in parallel with the preamplifier circuit.

### BACKGROUND

1. Field

The disclosure relates to a method and apparatus for providing low-voltage differential signaling (“LVDS”) with common mode noise suppression. More specifically, the disclosure relates to a method and apparatus for noise suppression in an LVDS receiver by providing improved common mode noise immunity through a bypass circuit.

2. Related Art

Low-voltage differential signaling is a relatively new technology suitable for high performance data transmission applications. The popularity of LVDS is driven by its ability to provide high data rates while consuming significantly less power than competing technologies. The data rate of the LVDS system is in the gigabits per sec (Gbps) range while power consumption is in the milli-watts range.

LVDS uses two signal lines to convey information. The cost of using LVDS is having two traces to conduct a signal. However, the gain is an exceptional noise tolerance in the form of common-mode rejection, allowing signal swing to be reduced to only a few hundred millivolts. Thus, LVDS provides a low-swing, differential signaling method which allows single channel data transmission at data rates above Gbps. Its low swing and current-mode driver output provide low noise and low power consumption across a wide range of frequencies.

LVDS receivers are susceptible to sudden changes in the common mode voltage at the input. The sudden change causes jitter in the received signal, and noise in the entire system. If the noise is sufficiently high, a complete data cycle can be skipped by the receiver if the sudden noise pushes the receiver front-end beyond its common mode range. A conventional method for addressing this problem includes processing the signal through passive circuit elements such capacitors and resistors prior to processing the signal to decouple common mode from transmitted signal. Signals with inherent periodicity can be transmitted using such decoupling networks. If the original signal has a DC component, encoding is required to make sure that the data stream has enough transitions to be passed through DC blocking capacitor with negligible loss. However, this is sometimes not desired due to increased complexity and encoding overhead. Thus, there is a need for a method and apparatus to provide a LVDS receiver with common mode noise suppression that can work from DC to high data rates.

### SUMMARY

In one embodiment, the disclosure relates to a method for providing LVDS signaling, where the signal information is carried on two lines that have same magnitude voltage swing with opposite polarities with respect to a common mode voltage level. In one embodiment, the method includes the following steps: receiving a first and a second input signals; converting the input voltage to current using a transconductance preamplifier; blocking the DC component of the signal through the transconductance preamplifier and bypassing the AC component of the input signal using bypass capacitors; converting the current back to voltage using a plurality of pull-up devices; and amplifying the converted current using a second amplifier.

In another embodiment, the disclosure relates to an apparatus for providing Low Voltage Differential signaling (LVDS), the apparatus comprising: a preamplifier circuit for receiving a DC component of a first signal and providing a processed DC signal; a first bypass circuit for receiving an AC component of the first signal, the first bypass circuit providing a first AC output signal; a first node for combining the processed DC signal with the first AC output signal to form a first combined output signal; and an amplifier circuit for amplifying the first combined output signal and a second signal to provide a first amplified signal and a second amplified signal, wherein the first bypass circuit is in parallel with the preamplifier circuit.

In still another embodiment, the disclosure relates to an apparatus for providing low voltage differential signaling, the apparatus comprising: a preamplifier circuit for receiving a DC component of a first signal and a DC component of a second signal, the preamplifier outputting a first processed DC signal and a second processed DC signal; a first bypass circuit for receiving an AC component of the first signal, the first bypass circuit outputting a first AC output signal; a second bypass circuit for receiving and AC component of the second signal, the second bypass circuit outputting a second AC output signal; a first node for combining the first processed DC signal and the first AC output signal to provide a first combined output; a second node for combining the second processed DC signal and the second AC output signal to provide a second combined output; and an amplifier circuit for amplifying the first combined output to provide a first amplified signal, the amplifier circuit amplifying the second combined output to provide a second amplified circuit, wherein the first bypass circuit and the second bypass circuit are in parallel with the preamplifier circuit.

### BRIEF DESCRIPTION OF THE DRAWINGS

These and other embodiments of the disclosure will be discussed with reference to the following non-limiting and exemplary illustrations in which like elements are numbered similarly, and where:

FIG. 1 is a schematic representation of a circuit according to one embodiment of the disclosure;

FIG. 2 is a transconductance circuit according to another embodiment of the disclosure;

FIG. 3 schematically represents a built-in hysteresis voltage diagram for the second stage amplifier according to one embodiment of the disclosure;

FIG. 4 is a representative algorithm according to one embodiment of the disclosure; and

FIG. 5 is a representative algorithm according to another embodiment of the disclosure.

### DETAILED DESCRIPTION

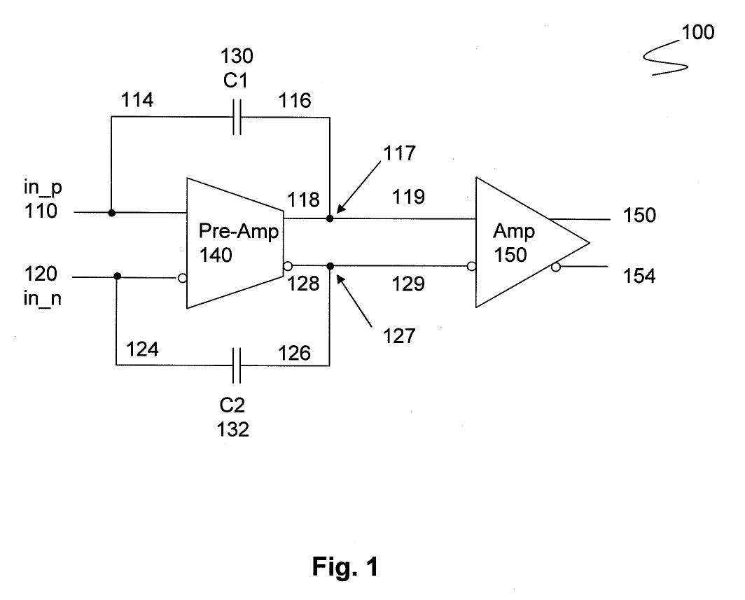

FIG. 1 is a schematic representation of a circuit according to one embodiment of the disclosure. Referring to FIG. 1, circuit 100 receives first input signal 110 and second input signal 120. The first input signal 110 comprises an AC signal component 114 and a DC signal component 112. Similarly, the second input signal 120 comprises AC signal component 124 and DC signal component 122. At node 111, AC signal component 114 is separated from DC signal component 112. At node 121, AC signal component 124 of second signal 120 is separated from DC signal component 122.

In one embodiment of the disclosure, the AC and the DC components of the incoming signals are separated such that a spike in the AC signal does not affect the signaling. Thus, in the embodiment of FIG. 1, DC component 112 of first signal 110 is processed through preamplifier circuit 140 while AC component 114 of first signal 110 is directed to first capacitor 130. First capacitor 130 defines a first bypass circuit. Similarly, DC component 122 of second signal 120 is directed to preamplifier circuit 140 while AC component 124 of second signal 120 is directed to second capacitor 132. Second capacitor 132 defines a second bypass circuit. First capacitor 130 and second capacitor 132 advantageously isolate and control any spike in first signal 110 and second signal 120, respectively.

It should be noted that while the embodiment of FIG. 1 shows first capacitor 130 and second capacitor 132, other circuit elements or other circuits can be used to obtain the same result. Namely, any circuit elements or circuits can be used as long as such circuit is able to absorb fluctuations in the AC signal. The fluctuation in the AC signal can comprise a current spike, etc.

The DC component of first signal 112 and DC component of second signal 122 are processed through preamplifier circuit 140. Preamplifier circuit 140 can have a gain of 1, 1.5, 2 or other suitable gains. In one embodiment, preamplifier circuit 140 applies a unity gain to each of DC component signal 112 and DC component signal 122. Consequently, first processed DC signal 118 is substantially identical to DC component of first signal 112 and second processed DC signal 128 is substantially identical to DC component of second signal 122.

As stated, AC component of first signal 114 is processed through first capacitor 130 to obtain first AC output signal 116. AC component of second signal 124 is processed through second capacitor 132 to obtain second AC output signal 126. At first node 117, first AC output signal 116 is combined with first processed DC signal 118. Similarly, at second node 127, second processed DC signal 128 is combined with second AC output signal 126. Each of first node 117 and second node 127 can define a node, an adder or a junction.

First combined output 119 and second combined output 129 are directed to amplifier circuit 150. Amplifier circuit 150 can comprise a conventional amplifier circuit. Amplifier circuit 150 can have a sufficiently high gain to convert LVDS level to CMOS level (e.g., from 350 mV to 3.5 V). As discussed in greater detail below, the built-in hysteresis prevents output from changing when differential signals dwell around 0 volts. Such event can occur during signal transition or when pre-amplifier 140 is turned off in response to an out-of-range input common mode voltage.

The output from amplifier circuit 150 comprises first amplified signal 152 and second amplified signal 154. First amplified signal 152 and second amplified signal 154 can provide the input to a receiver circuit (not shown). Advantageously, the common mode voltage is set internally at the preamplifier circuit 140, hence there is less jitter noise in the main amplifier 150. Thus, in the case of large and sudden common mode jump, DC path provides sufficient gain even though the AC path is momentarily turned off or isolated.

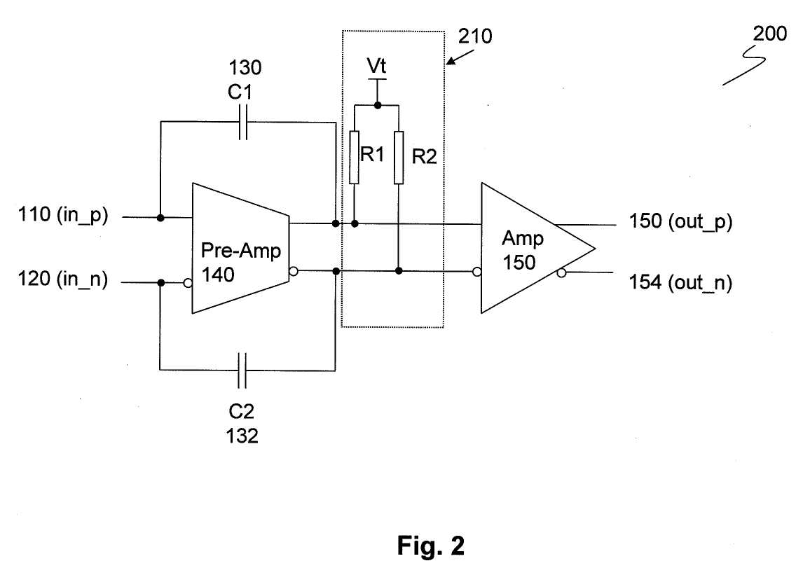

FIG. 2 is a transconductance circuit according to another embodiment of the disclosure. Circuit 200 of FIG. 2 is similar to circuit 100 of FIG. 1, except for the addition of pull-up resistors R₁ and R₂.

In circuit 200, the signal information is carried on lines 110 and 120 which have same magnitude voltage swing with opposite polarities with respect to a common mode voltage level. Pre-amplifier 140 can be a transconductance amplifier for converting the input differential voltage to differential output currents. Preamplifier 140 can be connected to an internal termination network 210, which sets the internal common mode voltage and converts current signal back to voltage. Amplifier 150 can process both AC and DC components, as long as the incoming signal is within its common mode input range, which is typically from 0.2V to 2.2V. There is also a parallel signal path from differential inputs, where inputs are bypassed by capacitors 130 and 132 to the internal termination network. Bypass capacitors 130, 132 only pass the AC level of the signal, independent of the input common mode voltage. The gain of the pre-amplifier 140 can be adjusted to be unity, such that the current through the bypass capacitors 130, 132 is 0, hence the circuitry is not loaded as long as the input signals are within the common mode range of pre-amplifier 140. Signal at the internal termination network can be amplified by a second amplifier stage 150, which convert its inputs from LVDS level (e.g., 1V-1.4V) to CMOS level (e.g., 0V-3.3V). Furthermore, amplifier 150 can have a built-in hysteresis for suppressing noise when the differential input signal crosses zero level.

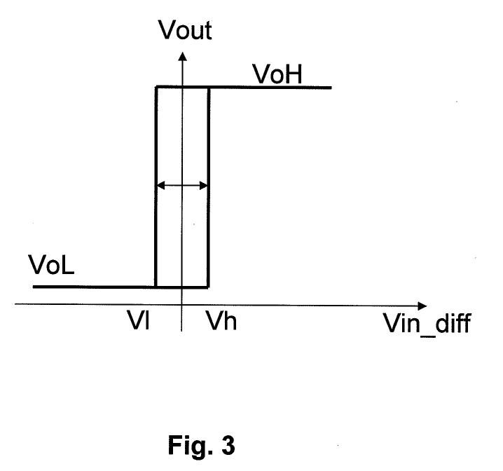

FIG. 3 schematically represents a built-in hysteresis voltage diagram for amplifier 150. A built-in hysteresis can prevent state changes at the output of the second stage (i.e., amplifier 150) even if its inputs are held at the same potential with zero differential voltage. This occurs when preamplifier 140 turns off if the receiver inputs exceed its common mode range, and only the AC component of the signal can be passed through the integrated bypass capacitors. Therefore, hysteresis network can also be considered a feature that remembers the DC component of the signal, and compensates for the loss of the DC component due to out-of-range common mode variations.

Referring to FIGS. 2 and 3, the gain of preamplifier 140 can be identified as the transconductance gain, or Gm. The resistance of termination network 210 can be described as:

Termination network: R1=R2=R (1)

It should be noted that termination network 210 can be implemented using diode connected pull-up transistors (not shown). If diode connected pull-up transistors are used, the resistance will be equal to 1/gm (where gm is the transconductance gain). For the bypass network, the following relationship applies:

C1=C2=C (2)

Thus, the gain in the first stage (or, the preamplifier stage) can be chosen such that:

Gm*R=1 (3)

With this relationship, there will be no current through the caps as long as the inputs are within the common mode range of preamplifier 140. In one embodiment of the disclosure, C should be selected such that time constant R*C does not limit the speed of operation (that is, R*C<T_{bit}/2; where T_{bit} is the shortest input pulse width). When the input falls outside the common mode range, pre-amp turns off and the current proportional to the AC component in the signal flows into the termination network by blocking the input DC level.

Having blocked the DC current, steady input levels result in zero differential voltage at the termination network outputs. Therefore, the second amplifier stage (amplifier 150) needs to have a built-in hysteresis in order to prevent the output state to change in response to noise at the termination network. Thus, in FIG. 3 even if the input differential voltage is set to zero, the output preserves its last state due to the built-in hysteresis voltage. The input to the amplifier should go lower than V_{I} or higher than Vₕ to register a change in the output state.

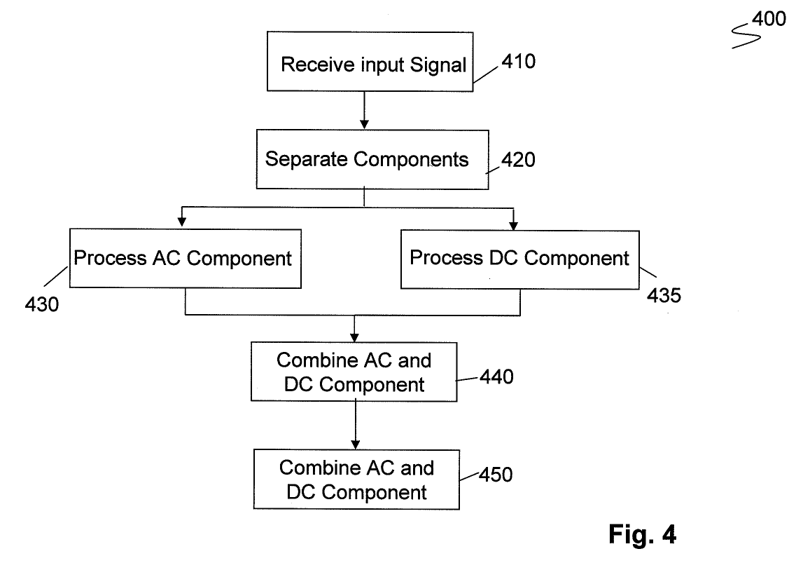

FIG. 4 is a representative algorithm according to one embodiment of the disclosure. The process of FIG. 4 starts at step 410, where a first and a second input signal are received. Each of the first and the second input signals comprises an AC and a DC component. In step 420, the AC and the DC components of each of the first and the second signals are separated. In step 430, the AC components for the first and the second signal are directed to a bypass circuit. In one embodiment, the AC component of the first signal is directed to a first bypass circuit and the AC component of the second signal is directed to a second bypass circuit.

In step 435, the DC component of the first signal and the DC component of the second signal are directed to a preamplifier circuit. The preamplifier circuit can define a conventional amplifier with a unity gain. In one embodiment of the disclosure, the DC component of the first signal and the DC component of the second signal are directed to a preamplifier circuit. In another embodiment, the DC component of the first signal is directed to a first preamplifier circuit while the DC component of the second signal is directed to a second preamplifier circuit.

In step 440, the DC component of the first signal is combined with the AC component of the first signal. In addition, the AC component of the second signal is combined with the DC component of the second signal. Thus, a first signal and a second signal are reformed after being processed through bypass circuits and preamplifier circuit(s). Finally, in step 450, the first and the second circuits are processed through an amplifier circuit having a gain, G.

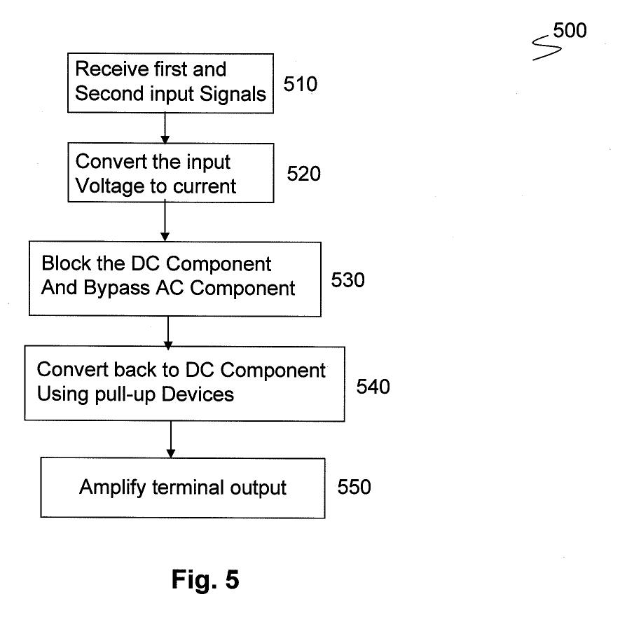

FIG. 5 is a representative algorithm according to another embodiment of the disclosure. Algorithm 500 of FIG. 5 starts in step 510 by receiving first and second input signals. Each input signals can have an AC and a DC component. In step 520, the input voltage is converted to a current signal using a transconductance amplifier (or, a preamplifier). The input DC component is blocked and the AC input component is bypassed using bypass capacitors in step 530. Thus, the AC component is bypasses the transconductance amplifier. In step 540, pull-up devices are used between the output of the transconductance amplifier and the input to the subsequent amplifier stage. The pull-up devices between the internal termination voltage and the transconductance preamplifier circuit convert the current back to voltage. Thus, the AC component is inputted into a second stage amplifier. In step 550, the output of the termination network is amplified by the second stage amplifier. Typically, the gain can be made sufficiently high to convert LVDS levels to CMOS levels (e.g., from 350 mV to 3.3V).

While the specification has been disclosed in relation to the exemplary and non-limiting embodiments provided herein, it is noted that the inventive principles are not limited to these embodiments and include other permutations and deviations without departing from the spirit of the disclosure. For example, while the exemplary embodiments are directed to a combination filter device protecting human eyes from laser, the principles can be used to filter out photons of any undesirable wavelength or wavelengths.

1. A method for providing LVDS signaling, the method comprising:
providing a first input signal having a first AC component and a first DC component;
providing a second input signal having a second AC component and a second DC component;
receiving the first DC component and the second DC component at a preamplifier circuit, the preamplifier circuit applying a primary gain to the first DC component and the second DC component to provide a first DC output and a second DC output;
directing the first AC component to a first bypass circuit to obtain a first AC output;
combining the first AC output with the first DC output to obtain a first combined output;
combining the second AC output with the second AC component to obtain a second combined output; and
processing each of the first combined output and the second combined output at a second amplifier circuit to apply a secondary gain to each of the first combined output and the second combined output to thereby provide a first amplified output and a second amplified output.

2. The method of claim 1, further comprising separating the first AC component and the first DC component from the first input signal.

3. The method of claim 1, wherein the primary gain is selected from the group consisting of 1, 1.5 and 2.

4. The method of claim 1, wherein the first bypass circuit is a capacitor.

5. The method of claim 1, wherein the step of combining the first DC output with the first AC output is implemented at a node.

6. The method of claim 1, further comprising directing the second AC component to a second bypass circuit.

7. An apparatus for providing Low Voltage Differential signaling (LVDS), the apparatus comprising:
a preamplifier circuit for receiving a DC component of a first signal and providing a first processed DC signal;
a first bypass circuit for receiving an AC component of the first signal, the first bypass circuit providing a first AC output signal;
a first node for combining the processed DC signal with the first AC output signal to form a first combined output signal; and
an amplifier circuit for amplifying the first combined output signal and a second signal to provide a first amplified signal and a second amplified signal,
wherein the first bypass circuit is in parallel with the preamplifier circuit.

8. The apparatus of claim 7, wherein the preamplifier circuit provides a primary gain selected from the group consisting of 1, 1.5 and 2.

9. The apparatus of claim 7, wherein the first bypass circuit defines one or more capacitors.

10. The apparatus of claim 7, wherein the first node defines a junction for combining the first DC output with the first AC output signal.

11. The apparatus of claim 10, further comprising a second bypass circuit for receiving an AC component of the second signal, the second bypass circuit outputting a second AC output signal.

12. The apparatus of claim 10, further comprising a second node for combining the second AC output signal with a DC component of the second signal.

13. The apparatus of claim 10, wherein the preamplifier circuit independently processes the DC component of the first signal and the DC component of the second signal.

14. The apparatus of claim 10, wherein the second bypass circuit is in parallel with at least one of the preamplifier circuit or the first bypass circuit.

15. An apparatus for providing low voltage differential signaling, the apparatus comprising:
a preamplifier circuit for receiving a DC component of a first signal and a DC component of a second signal, the preamplifier outputting a first processed DC signal and a second processed DC signal;
a first bypass circuit for receiving an AC component of the first signal, the first bypass circuit outputting a first AC output signal;
a second bypass circuit for receiving and AC component of the second signal, the second bypass circuit outputting a second AC output signal;
a first node for combining the first processed DC signal and the first AC output signal to provide a first combined output;
a second node for combining the second processed DC signal and the second AC output signal to provide a second combined output; and
an amplifier circuit for amplifying the first combined output to provide a first amplified signal, the amplifier circuit amplifying the second combined output to provide a second amplified circuit,
wherein the first bypass circuit and the second bypass circuit are in parallel with the preamplifier circuit.

16. The apparatus of claim 15, wherein the preamplifier circuit provides a gain selected from the group consisting of 1, 1.5 and 2.

17. The apparatus of claim 15, wherein the first bypass circuit is a passive circuit.

18. The apparatus of claim 15, wherein the first bypass circuit defines one or more capacitors.

19. The apparatus of claim 15, wherein the first node defines an adder for combining the first DC output with the first AC output.

20. The apparatus of claim 15, wherein the first node defines a junction for combining the first DC output with the first AC output.
